(19) United States
(12) Patent Application Publication
(10) Pub. No.: US 2025/0175136 A1
(43) Pub. Date: May 29, 2025

(54) Dynamic Amplitude Adjustment of Analog Input Signals

(71) Applicant: Bendix Commercial Vehicle Systems LLC, Avon, OH (US)

(72) Inventors: Amit Babalal Nahar, Pune (IN); Dattatray Jadhav, Aurangabad (IN); Akshay Mishra, Kanpur (IN)

(21) Appl. No.: 18/425,055

(22) Filed: Jan. 29, 2024

(30) Foreign Application Priority Data
Nov. 29, 2023 (IN) 202341080924

(51) Int. Cl. H03G 3/30; H03F 3/24; H03G 1/00; H04B 3/54

(52) U.S. Cl. CPC H03G 3/3052; H03F 3/245; H03G 1/0017; H04B 3/542; H03F 2200/451

(57) ABSTRACT

A circuit for adjusting an amplitude of an analog input signal includes an amplifier configured to receive the analog input signal and to output an analog output signal responsive to the analog input signal and a gain control signal. A gain control signal generator is also configured to receive the analog input signal and to generate the gain control signal responsive to the analog input signal.

### BACKGROUND OF THE INVENTION

### a. Field of the Invention

This invention relates to signal conditioning. In particular, the invention relates to a circuit and method for adjusting the amplitude of an analog input signal to a level suitable for further processing of the signal.

### b. Background Art

Analog electrical signals that are received by or input to certain systems may have amplitudes having a large dynamic range. For example, Power Line Communication (PLC) is a communication method in which data is transmitted over wires that are also used to deliver electric power. The data is encoded within a signal that is transmitted over the wires in frequency ranges outside of those used to transmit electric power. PLC is advantageous relative to other communication methods because it enables communication using existing wiring. Tractor-trailers frequently employ PLC to exchange messages between members of the tractor-trailer including, for example, sensor readings from vehicle systems including anti-lock braking systems, collision avoidance systems, tire pressure monitoring systems and other vehicle systems as well as commands used to control anti-lock braking systems, lighting systems and other vehicle systems. In accordance with the communications protocol developed by the Society of Automotive Engineers (SAE) and set forth in a document number J2497 and titled “Power Line Carrier Communications for Commercial Vehicles”, PLC signals have a large dynamic range with signals have voltages between five (5) millivolts peak-to-peak and seven thousand (7000) millivolts peak-to-peak. Because of the large dynamic range of such signals, the amplitude must be adjusted prior to processing (e.g., demodulation and decoding) of the signals to allow for processing in a reliable and efficient manner.

Conventional circuits and methods for adjusting signal amplitude frequently employ complex integrated circuits that require repeated conversions of the analog signal to a digital signal and from a digital signal back to an analog signal. Conventional circuits and methods also frequently require multiple stages of amplification or attenuation to amplify or attenuate a signal. Conventional circuits and methods also frequently compare signal amplitude against one or more thresholds in deciding whether or not to adjust the amplitude creating delays in further processing of the signal.

The inventors herein have recognized a need for a circuit and method for adjusting an amplitude of an analog input signal that will minimize and/or eliminate one or more of the above-identified deficiencies.

### BRIEF SUMMARY OF THE INVENTION

This invention relates to signal conditioning. In particular, the invention relates to a circuit and method for adjusting the amplitude of an analog input signal to a level suitable for further processing of the signal.

One embodiment of a circuit for adjusting an amplitude of an analog input signal includes an amplifier configured to receive the analog input signal and to output an analog output signal responsive to the analog input signal and a gain control signal. The circuit further includes a gain control signal generator configured to receive the analog input signal and to generate the gain control signal responsive to the analog input signal.

Another embodiment of a circuit for adjusting an amplitude of an analog input signal includes an amplifier configured to receive the analog input signal and to output an analog output signal responsive to the analog input signal and a gain control signal. The circuit further includes means for generating the gain control signal, the generating means configured to receive the analog input signal and to generate the gain control signal responsive to the analog input signal.

One embodiment of a method for adjusting an amplitude of an analog input signal includes receiving an analog input signal as an input to an amplifier and a gain control signal generator. The method further includes generating a gain control signal in the gain control signal generator responsive to the analog input signal. The method further includes outputting an analog output signal from the amplifier responsive to the analog input signal and the gain control signal.

A circuit and method for adjusting an amplitude of an analog input signal in accordance the present teachings represent an improvement as compared to conventional circuits and methods. In particular, the circuit and method disclosed herein employ less complex circuitry than conventional circuits and avoid the need for conversion of the analog signal to a digital signal and back to an analog signal. The circuit and method also adjust the amplitude in a single stage. Finally, the circuit and method avoid comparisons of the signal amplitude to predetermined thresholds and the resulting delays in adjustment of the amplitude and signal processing.

The foregoing and other aspects, features, details, utilities, and advantages of the present invention will be apparent from reading the following description and claims, and from reviewing the accompanying drawings.

### BRIEF DESCRIPTION OF THE DRAWINGS

FIG. 1 is a diagrammatic view of a vehicle in which analog signals are transmitted via Power Line Communication (PLC).

FIG. 2 is a diagrammatic view of one embodiment of a circuit for adjusting an amplitude of an analog input signal.

FIG. 3 is a schematic diagram of the circuit of FIG. 2.

FIGS. 4-6 are waveform diagrams showing waveforms for an analog input signal and a corresponding analog output signal output by the circuit of FIGS. 2-3.

### DETAILED DESCRIPTION OF THE INVENTION

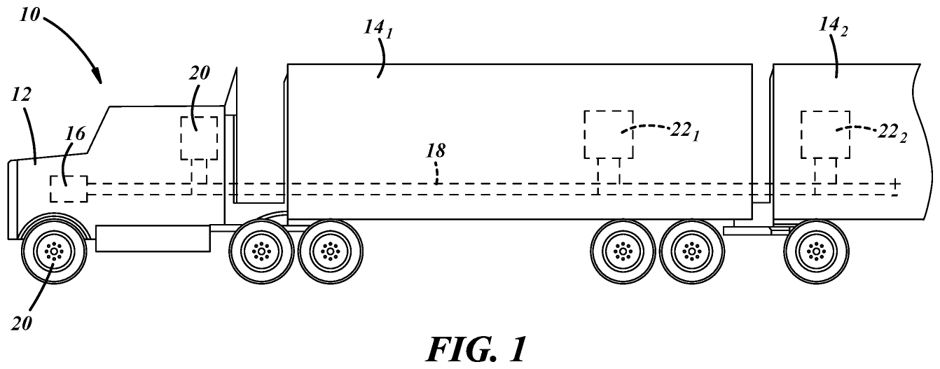

Referring now to the drawings wherein like reference numerals are used to identify identical components in the various views, FIG. 1 illustrates a tractor-trailer 10. Tractor-trailer 10 (also referred to as a semi) contains a truck or tractor 12 and one or more trailers 14₁ . . . 14_{N}. Tractor 12 contains a power unit, such as an internal combustion engine, and steering and drive axles. Tractor 12 also contains a battery 16 for use in starting the power unit and in providing power to various accessory systems. Trailers 14₁ . . . 14_{N} are provided to store freight and are detachably coupled to tractor 12. Although a pair of trailers 14 are shown in the illustrated embodiment, it should be understood that the number of trailers 14 attached to tractor 12 may vary.

Tractor 12 and trailers 14 may include various fluid and power lines that extend between tractor 12 and trailers 14 including power line 18. The fluid and power lines allow delivery of fluids and electrical power from tractor 12 to trailers 14 for use in, for example, tire pressure management, braking, and activation of tail lights on trailer 14. Power line 18 also forms part of a network used to transmit communications between various electronic systems 20, 22₁ . . . 22_{N} on tractor 12 and trailers 14, respectively. Systems 20, 22 may comprise any of a wide variety of systems commonly employed on tractor-trailer 10 including, for example, anti-lock braking systems, collision avoidance systems, tire pressure monitoring and control systems, trailer load monitoring systems, and lighting systems. Power line 18 may enable transmission of data from one or more systems 22 on trailers 14 to a system 20 on tractor 12 including, for example, sensor readings indicative of the operation of an anti-lock braking system, the location of surrounding vehicles and infrastructure, pressure within the tires on a trailer 14, or a shift in the load carried by a trailer 14. Power line 18 may also enable transmission of commands and data from tractor 12 to trailers 14 for use in controlling elements of an anti-lock braking system, tire pressure control system or lighting system on one or more of trailers 14.

Messages containing data and/or commands may be transmitted along power line 18 between systems 20, 22 using the communications protocol developed by the Society of Automotive Engineers (SAE) and set forth in the document number J2497 and titled “Power Line Carrier Communications for Commercial Vehicles.” In accordance with this protocol, the messages are encoded and transmitted as analog signals having a large dynamic range. In particular, the signals have voltages between five (5) millivolts peak-to-peak and seven thousand (7000) millivolts peak-to-peak. In order to reliability and efficiently process these signals, the amplitude of a received signals often requires adjustment (amplification or attenuation) prior to further processing of the signal.

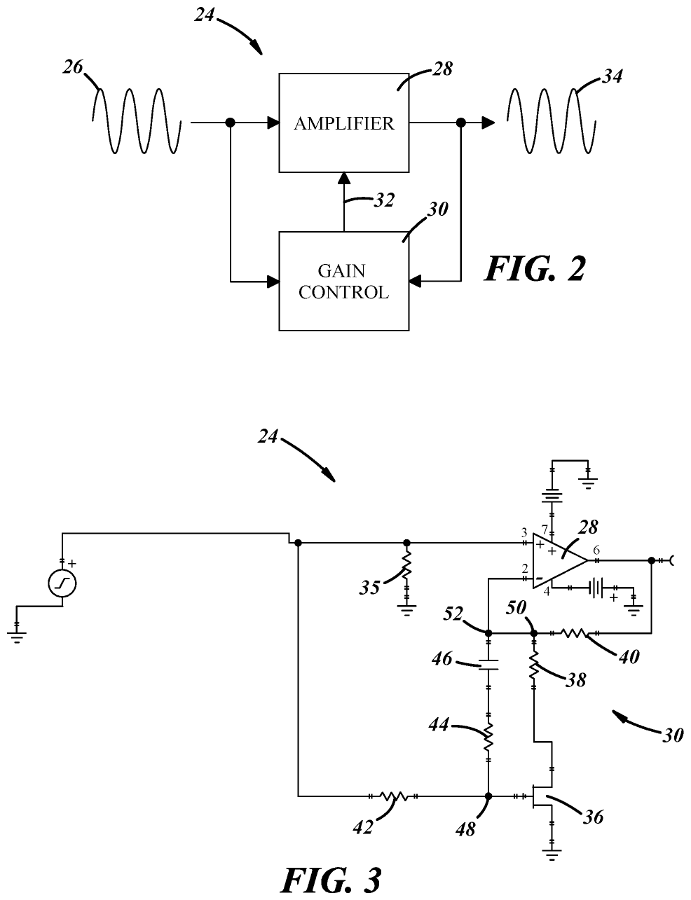

Referring now to FIGS. 2-3, one embodiment of a circuit 24 for adjusting an amplitude of an analog input signal 26 is illustrated. A similar circuit 24 may be present in each system 20, 22 on vehicle 10. Circuit 24 includes an amplifier 28 and means, such as gain control signal generator 30, for generating a gain control signal 32 for amplifier 28.

Amplifier 28 is configured to receive an analog input signal 26 and to output an analog output signal 34 that may have a different amplitude (i.e., amplified or attenuated) than the analog input signal 26. Amplifier 28 may for example, comprise the eight-pin operational amplifier offered by Texas Instruments, Inc. under part number LM318. Amplifier 28 receives two input signals—the analog input signal 26 (at pin 3 in the illustrated embodiment) and the gain control signal 32 (at pin 2 in the illustrated embodiment) from gain control signal generator 30. In response to these signals, amplifier 28 outputs an analog output signal 34 (at pin 6 in the illustrated embodiment). In accordance with the teachings disclosed herein, the amplitude of the analog output signal 34 will be increased relative to the amplitude of the analog input signal 26 when the amplitude of the analog input signal 26 is below a predetermined level. Conversely, the amplitude of the analog output signal 34 will be decreased relative to the amplitude of the analog input signal 26 when the amplitude of the analog input signal 26 is above the predetermined level. The amplitude of the analog output signal 34 will equal the amplitude of the analog input signal 26 when the amplitude of the analog input signal 26 is equal to the predetermined level. The predetermined level may be varied depending on the application and is reflected in the configuration of gain control signal generator 30 described below.

Gain control signal generator 30 provides means for generating a gain control signal 32 to control adjustment of the amplitude of the analog input signal 26 by amplifier 28. In accordance with the teachings disclosed herein, gain control signal generator 30 generates the gain control signal 32 responsive to the analog input signal 26 and the analog input signal 26 is the only variable in formulating the gain control signal 32. Referring to FIG. 2, gain control signal generator 30 is configured to receive the analog input signal 26 and to generate the gain control signal 32 responsive to the analog input signal 26.

Referring to FIG. 3, gain control signal generator 30 may include a n-channel junction field-effect transistor (JFET) 36, resistors 38, 40, 42, 44 and a capacitor 46. JFET 36 and resistors 38, 40 determine the configuration of gain control signal 32 and, therefore, the gain provided to amplifier 28. The gate of JFET 36 is tied to a node 48 configured to receive the analog input signal 26 which may be passed through resistor 42 prior to reaching node 48. The source of JFET 36 is tied to ground while the drain of JFET 36 is in series with resistor 38. Resistor 38 is disposed between the drain of JFET 36 and a node 50. Resistor 40 is disposed between the output of amplifier 28 and node 50 that is tied, through node 52, to the inverting input of amplifier 28. Amplifier 28 is therefore configured with negative feedback to provide a stable output based on the gain. Resistor 42 and capacitor 44 act as an offset minimizing circuit to minimize the offset current of amplifier 28 and as a low-pass filter to suppress high frequency noise in gain control signal generator 32. Resistor 42 and capacitor 44 are arranged in series between node 38 and node 52 which is tied to node 50 and the inverting input of amplifier 28 and at which the gain control signal 32 is formed and output to amplifier 28.

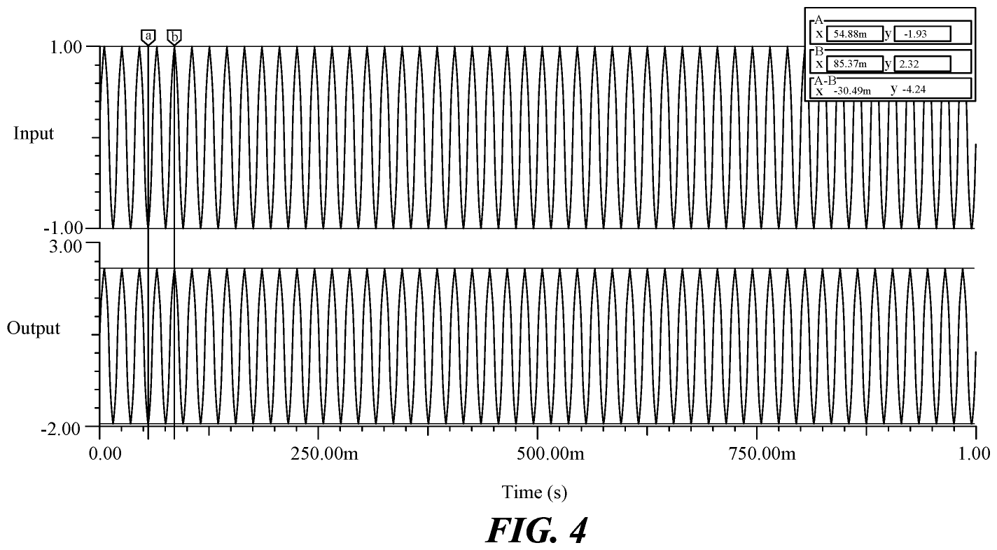

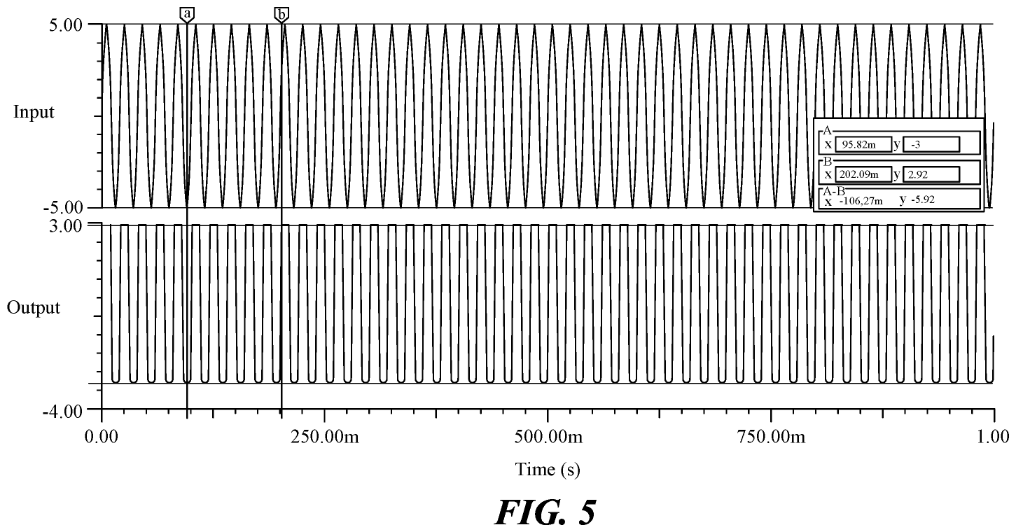

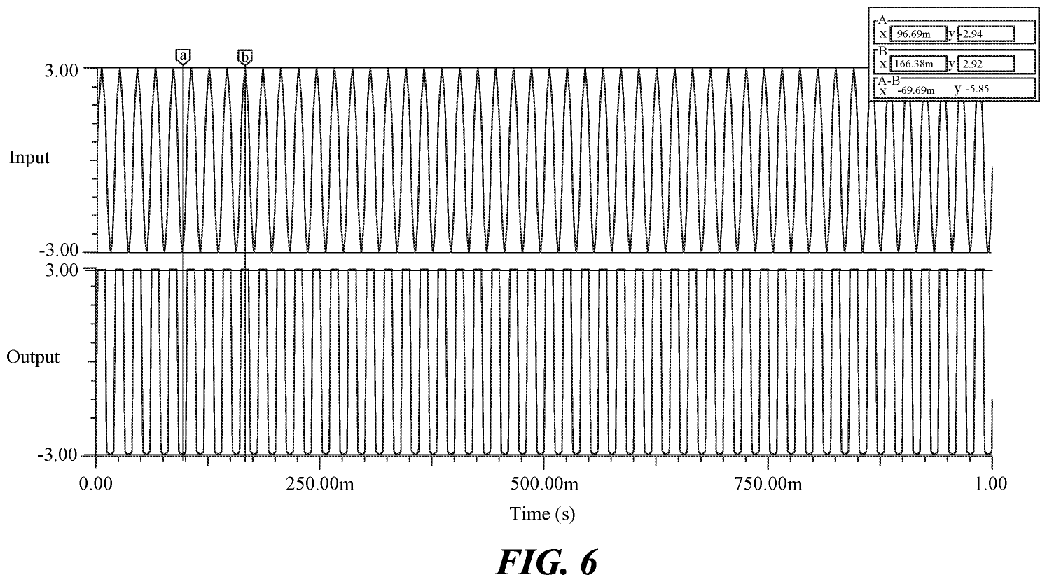

The configuration of gain control signal generator 30 produces a gain control signal 32 establishing a gain in amplifier 28 that is inversely proportional to the amplitude of the analog input signal 26. In particular, JFET 36 functions as a variable resistor with the resistance between the drain and source of JFET 36 increasing as the voltage between the gate of JFET 36 and source of JFET 36 increases. The voltage between the gate and source of JFET 36 is determined by the voltage of analog input signal 26. Therefore, as the voltage, and amplitude, of analog input signal 26 increases, the resistance of JFET 36 increases and the resulting gain control signal 32 provided to amplifier 28 establishes a gain in amplifier 28 that is inversely proportional to the amplitude of analog input signal 26. Referring to FIG. 4, in one embodiment amplifier 28 will generate an analog output signal 34 having an increased amplitude (2.25 Volts peak to peak) relative to the amplitude of the analog input signal 26 (1 Volt peak to peak) when the amplitude of the analog input signal 26 is below a predetermined level (3 Volts). Referring to FIG. 5, amplifier 28 will generate an analog output signal 34 having a decreased amplitude (3 Volts peak to peak) relative to the amplitude of the analog input signal 26 when the amplitude of the analog input signal 26 (5 Volts peak to peak) is above the predetermined level. Finally, referring to FIG. 6, amplifier 28 will generate an analog output signal 34 having an amplitude (3 Volts) that is equal to the amplitude of the analog input signal 26 (3 Volts) when the amplitude of the analog input signal 26 is equal to the predetermined level. The properties of the individual circuit elements 36, 38, 40, 42, 44, 46 of gain control circuit 30 may be selected based on the chosen predetermined level of amplitude.

Referring again to FIG. 2-3, a method for adjusting an amplitude of an analog input signal 26 may begin with the step of receiving the analog input signal 26 as an input to amplifier 28 and gain control signal generator 30. The method may continue with the step of generating a gain control signal 32 in the gain control signal generator 30 responsive to the analog input signal 26. As discussed above, in accordance with the present teachings, the analog input signal 26 is the only variable in generating the gain control signal 32 and the gain control signal 32 establishes a gain in amplifier 28 that is inversely proportional to the amplitude of the analog input signal 26. The method may conclude with the step of outputting an analog output signal 34 from amplifier 28 responsive to the analog input signal 26 and the gain control signal 32. Again, the analog output signal 34 will have an increased amplitude relative to the amplitude of the analog input signal 26 when the amplitude of the analog input signal 26 is below a predetermined level, a decreased amplitude relative to the amplitude of the analog input signal 26 when the amplitude of the analog input signal 26 is above the predetermined level, and an amplitude that is equal to the amplitude of the analog input signal 26 when the amplitude of the analog input signal 26 is equal to the predetermined level.

A circuit 24 and method for adjusting an amplitude of an analog input signal 26 in accordance the present teachings represent an improvement as compared to conventional circuits and methods. In particular, the circuit 24 and method disclosed herein employ less complex circuitry than conventional circuits and avoid the need for conversion of the analog input signal 26 to a digital signal and back to an analog signal. The circuit 24 and method also adjust the amplitude in a single stage. Finally, the circuit 24 and method avoid comparisons of the signal amplitude to predetermined thresholds and the resulting delays in adjustment of the amplitude and signal processing.

While the invention has been shown and described with reference to one or more particular embodiments thereof, it will be understood by those of skill in the art that various changes and modifications can be made without departing from the spirit and scope of the invention.

What is claimed is:

1. A circuit for adjusting an amplitude of an analog input signal, comprising:
an amplifier configured to receive the analog input signal and to output an analog output signal responsive to the analog input signal and a gain control signal; and,
a gain control signal generator configured to receive the analog input signal and to generate the gain control signal responsive to the analog input signal.

2. The circuit of claim 1 wherein a gain of the amplifier is established in response to the gain control signal and the gain is inversely proportional to the amplitude of the analog input signal.

3. The circuit of claim 1 wherein an amplitude of the analog output signal is increased relative to the amplitude of the analog input signal when the amplitude of the analog input signal is below a predetermined level.

4. The circuit of claim 3 wherein the amplitude of the analog output signal is decreased relative to the amplitude of the analog input signal when the amplitude of the analog input signal is above the predetermined level.

5. The circuit of claim 4 wherein the amplitude of the analog output signal is equal to the amplitude of the analog input signal when the amplitude of the analog input signal is equal to the predetermined level.

6. The circuit of claim 1 wherein the analog input signal is the only variable in formulating the gain control signal.

7. A circuit for adjusting an amplitude of an analog input signal, comprising:
an amplifier configured to receive the analog input signal and to output an analog output signal responsive to the analog input signal and a gain control signal; and,
means for generating the gain control signal, the generating means configured to receive the analog input signal and to generate the gain control signal responsive to the analog input signal.

8. The circuit of claim 7 wherein a gain of the amplifier is established in response to the gain control signal and the gain is inversely proportional to the amplitude of the analog input signal.

9. The circuit of claim 7 wherein an amplitude of the analog output signal is increased relative to the amplitude of the analog input signal when the amplitude of the analog input signal is below a predetermined level.

10. The circuit of claim 9 wherein the amplitude of the analog output signal is decreased relative to the amplitude of the analog input signal when the amplitude of the analog input signal is above the predetermined level.

11. The circuit of claim 10 wherein the amplitude of the analog output signal is equal to the amplitude of the analog input signal when the amplitude of the analog input signal is equal to the predetermined level.

12. The circuit of claim 7 wherein the analog input signal is the only variable in formulating the gain control signal.

13. A method for adjusting an amplitude of an analog input signal, comprising:
receiving an analog input signal as an input to an amplifier and a gain control signal generator;
generating a gain control signal in the gain control signal generator responsive to the analog input signal; and,
outputting an analog output signal from the amplifier responsive to the analog input signal and the gain control signal.

14. The method of claim 13 wherein a gain of the amplifier is established in response to the gain control signal and the gain is inversely proportional to the amplitude of the analog input signal.

15. The method of claim 13 wherein an amplitude of the analog output signal is increased relative to the amplitude of the analog input signal when the amplitude of the analog input signal is below a predetermined level.

16. The method of claim 15 wherein the amplitude of the analog output signal is decreased relative to the amplitude of the analog input signal when the amplitude of the analog input signal is above the predetermined level.

17. The method of claim 16 wherein the amplitude of the analog output signal is equal to the amplitude of the analog input signal when the amplitude of the analog input signal is equal to the predetermined level.

18. The method of claim 13 wherein the analog input signal is the only variable in formulating the gain control signal.
